(19) United States
(12) Patent Application Publication
(10) Pub. No.: US 2026/0161093 A1
(43) Pub. Date: Jun. 11, 2026

(54) EXCITATION LASER SYSTEM, METHOD OF OPERATING EXCITATION LASER SYSTEM, AND EXTREME ULTRAVIOLET PHOTOLITHOGRAPY APPARATUS INCLUDING EXCITATION LASER SYSTEM

(71) Applicant: Taiwan Semiconductor Manufacturing Company, Ltd., Hsinchu (TW)

(72) Inventors: Chih-Feng LU, Hsinchu (TW); Han-Lung CHANG, Hsinchu (TW); Chun-Lin CHANG, Hsinchu (TW); Wei-Huai CHIU, Hsinchu (TW); Li-Jui CHEN, Hsinchu (TW); Yung-Kuang CHEN, Hsinchu (TW)

(73) Assignee: Taiwan Semiconductor Manufacturing Company, Ltd., Hsinchu (TW)

(21) Appl. No.: 18/972,532

(22) Filed: Dec. 6, 2024

(51) Int. Cl. G03F 7/00; H01S 3/036; H01S 3/223

(52) U.S. Cl. CPC G03F 7/70033; G03F 7/70558; H01S 3/036; H01S 3/2232

(57) ABSTRACT

A method of operating an excitation laser system includes measuring an operating power of a laser beam, determining whether the operating power is below a threshold power value, optically measuring a spectrum of light emitted from a gain medium of the laser beam to determine a composition of the gain medium, and adjusting the composition of the gain medium based on the optical measurement. An apparatus includes an optical emission spectrum meter configured to capture a spectrum of light emitted from a gain medium of a laser beam, and a gas supply unit configured to control a supply of gas to the gain medium based on a composition of the gain medium determined from the spectrum of light.

### BACKGROUND

With advances in semiconductor device technology, photolithography processes have evolved to form increasingly smaller and more compact device structures. One photolithography technique is extreme ultraviolet (EUV) photolithography. EUV photolithography utilizes a laser to irradiate a target material to generate ultraviolet light. However, the power of a laser utilized in EUV photolithography can degrade over time, causing inconsistency in the process.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 and 2 show EUV lithography apparatuses according to embodiments of the disclosure.

FIG. 3 shows an excitation laser system according to an embodiment of the disclosure.

FIG. 4 shows a laser generator according to an embodiment of the disclosure.

FIG. 5 shows a laser amplifier according to an embodiment of the disclosure.

FIG. 6 shows an optical emission spectrum meter capturing light emitted from a laser generator according to an embodiment of the disclosure.

FIG. 7 shows components of an optical emission spectrum meter capturing light emitted from a laser generator according to an embodiment of the disclosure.

FIGS. 8A, 8B, and 9 show optical emission spectra according to embodiments of the disclosure.

FIG. 10 shows a plot of laser power from a laser generator over a period of time, overlaid with plots optical emission spectra emitted from the laser generator over the same period of time, according to an embodiment.

FIG. 11 shows a flow chart of a method of operating an excitation laser system according to an embodiment.

FIG. 12 shows a flow chart of a method of operating an excitation laser system according to an embodiment.

FIG. 13 shows a computing system according to an embodiment.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the methods and processes described herein, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

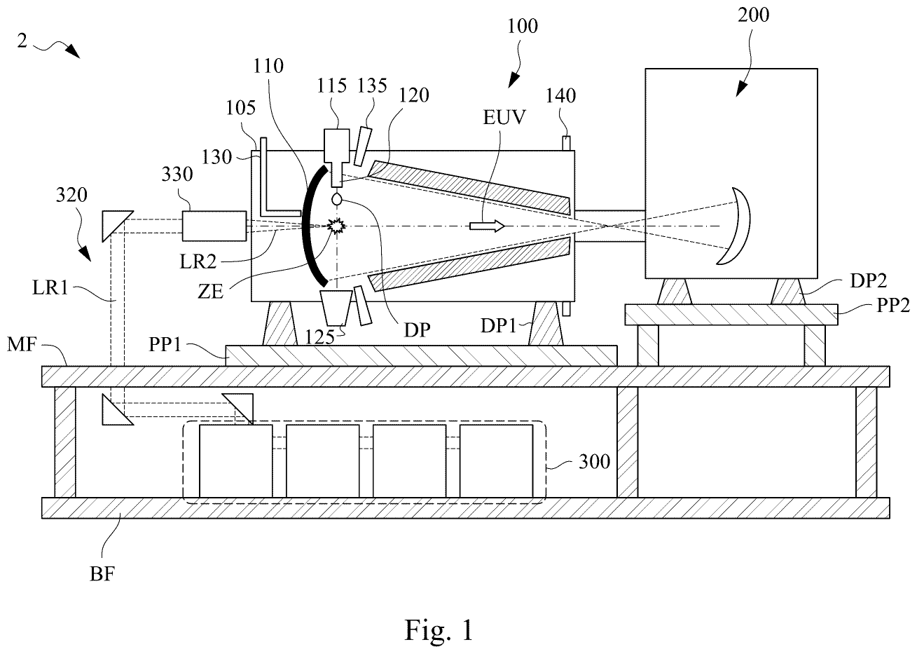

FIG. 1 is a schematic view of an EUV lithography apparatus 2, in accordance with some embodiments of the present disclosure. The EUV lithography apparatus 2 includes an EUV radiation source 100 to generate EUV radiation, an exposure device 200 such as a scanner, and an excitation laser system 300. The EUV radiation source 100 and the exposure device 200 are installed on a main floor MF of a clean room, while the excitation laser system 300 is installed in a base floor BF located under the main floor. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography apparatus 2 is designed to expose a photoresist layer to EUV light (also interchangeably referred to herein as EUV radiation). The photoresist layer includes a material sensitive to the EUV light. The EUV lithography apparatus employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In some embodiments, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and a wafer holding mechanism. The EUV radiation generated by the EUV radiation source 100 is guided by the reflective optical components onto a mask secured on the mask stage. In some embodiments, the mask stage includes an electrostatic chuck (e-chuck) to secure the mask.

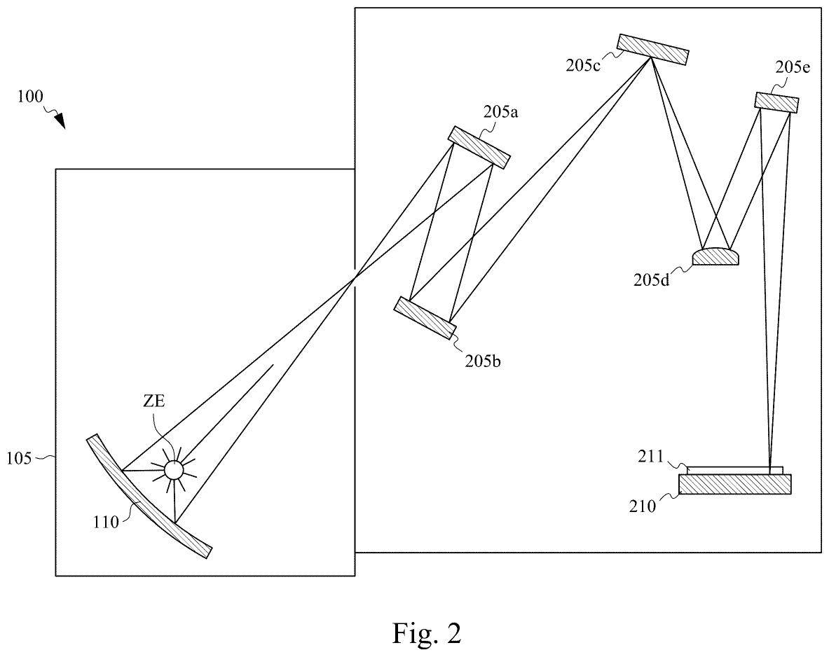

FIG. 2 is a simplified schematic diagram of a detail of an EUV lithography apparatus according to an embodiment showing the exposure of photoresist layer 211 coated on a substrate 210 with a patterned beam of EUV light. The exposure device 200 is an integrated circuit lithography apparatus such as a stepper, scanner, step and scan system, direct write system, a device using a contact and/or proximity mask, etc., provided with one or more optics 205a, 205b, for example, to illuminate a mask 205c (also referred to as a reticle or photomask) with a beam of EUV light, to produce a patterned beam, and one or more reduction projection optics 205d, 205e, for projecting the patterned beam onto the photoresist layer 211 disposed on the substrate 210. In the some embodiments, the mask 205c is a reflective mask. A mechanical assembly (not shown) may be provided for generating a controlled relative movement between the substrate 210 and mask 205c. The EUV radiation source 100 includes an EUV light radiator ZE emitting EUV light in a chamber 105 that is reflected by a mirror collector 110 along a path into the exposure device 200 to irradiate the photoresist layer 211 on the substrate 210. In some embodiments, the substrate 210 is a semiconductor substrate. In some embodiments, a semiconductor substrate is a semiconductor wafer, such as a silicon wafer or other type of wafer to be patterned.

In some embodiments, the mask 205c includes a reflective multilayered stack disposed over a substrate formed of a low thermal expansion material. In some embodiments, the reflective multilayered stack includes a plurality of film pairs, such as molybdenum-silicon (Mo/Si) film pairs (e.g., a layer of molybdenum above or below a layer of silicon in each film pair) or molybdenum-beryllium (Mo/Be) film pairs. In some embodiments, a capping layer is disposed over the reflective multilayered stack, and an absorber layer is disposed over the capping layer. A pattern can be formed in the absorber layer so that the mask reflects a pattern of light for exposure of the photoresist

As shown in FIG. 1, the EUV radiation source 100 includes a target droplet generator 115 and a mirror collector 110, enclosed by a chamber 105. In some embodiments, the target droplet generator 115 includes a reservoir to hold a source material and a nozzle 120 through which target droplets DP of the source material are supplied into the chamber 105. In some embodiments, the target droplets DP are droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz). A droplet catcher 125 is used for catching excessive target droplets. For example, some target droplets may be purposely missed by laser pulses.

In some embodiments, an excitation laser beam LR2 generated by the excitation laser system 300 is a pulse laser beam. In some embodiments, the excitation laser system includes a laser generator including a carbon dioxide (CO₂) laser source with a wavelength in the infrared region of the electromagnetic spectrum. For example, the laser generator emits a laser having a wavelength of about 9.4 μm or about 10.6 μm, in an embodiment. The laser beam LR1 generated by the excitation laser system 300 is guided by the laser guide optics 320 and focused into the excitation laser beam LR2 by the focusing apparatus 330, and then introduced into the EUV radiation source 100.

In some embodiments, the excitation laser beam LR2 includes a pre-heat laser beam and a main laser beam. In such embodiments, the pre-heat laser beam pulse (interchangeably referred to herein as the “pre-pulse) is used to heat (or pre-heat) a given target droplet to create a low-density target plume with multiple smaller droplets, which is subsequently heated (or reheated) by a pulse from the main laser beam, generating increased emission of EUV light. In some embodiments, the pre-heat laser beam pulses have a spot size about 100 μm or less, and the main laser beam pulses have a spot size in a range of about 150 μm to about 300 μm. In some embodiments, the pre-heat laser beam and the main laser beam pulses have a pulse-duration in the range from about 10 ns to about 50 ns, and a pulse-frequency in the range from about 1 kHz to about 100 kHz. In some embodiments, the pre-heat laser beam and the main laser beam have an average power in the range from about 1 kilowatt (kW) to about 50 kW. The pulse-frequency of the excitation laser LR2 is matched with the ejection frequency of the target droplets DP in an embodiment.

In some embodiments, the excitation laser beam LR2 is directed through windows (or lenses) into the zone of excitation ZE. The windows are made of a suitable material substantially transparent to the laser beams. The generation of the pulse laser beams is synchronized with the ejection of the target droplets DP through the nozzle 120. As the target droplets move through the excitation zone, the pre-pulse laser beams heat the target droplets and transform them into low-density target plumes. A delay between the pre-pulse and the main pulse laser beams is controlled to allow the target plume to form and to expand to an optimal size and geometry. In some embodiments, the pre-pulse and the main pulse laser beams have the same pulse duration and peak power. When the main pulse heats the target plume, a high-temperature plasma is generated. The plasma emits EUV radiation, which is collected by the mirror collector 110. The mirror collector 110 further reflects and focuses the EUV radiation for the lithography exposing processes performed through the exposure device 200. In some embodiments, the mirror collector 110 is designed to have an ellipsoidal geometry. In some embodiments, the mirror collector 110 is designed with a proper coating material and shape to function as a mirror for EUV collection, reflection, and focusing.

In some embodiments, a coating material of the mirror collector 110 is similar to a reflective multilayer of the EUV mask. In some examples, a coating material of the mirror collector 110 includes a reflective multilayer (such as a plurality of Mo/Si film pairs) and may further include a capping layer (such as Ru) coated on the reflective multilayer to substantially reflect the EUV light. In some embodiments, the mirror collector 110 may further include a grating structure designed to effectively scatter the laser beam directed onto the mirror collector 110. For example, a silicon nitride layer can be coated on the mirror collector 110 and patterned to have a grating pattern.

In such an EUV radiation source 100, the plasma caused by the laser application creates physical debris, such as ions, gases and atoms of the droplet, as well as the desired EUV radiation. It is necessary to prevent the accumulation of material on the mirror collector 110 and also to prevent physical debris exiting the chamber 105 and entering the exposure device 200. Because gas molecules absorb EUV light, the lithography system for the EUV lithography patterning can be maintained in a vacuum or a low-pressure environment to avoid EUV intensity loss. In some embodiments, a buffer gas is supplied from a first buffer gas supply 130 through the aperture in the mirror collector 110 by which the pulse laser is delivered to the tin droplets. In some embodiments, the buffer gas is H₂, He, Ar, N₂ or another inert gas. The buffer gas can also be provided through one or more second buffer gas supplies 135 toward the mirror collector 110 and/or around the edges of the mirror collector 110. Further, the chamber 105 includes one or more gas outlets 140 so that the buffer gas is exhausted outside the chamber 105. Hydrogen gas (H₂) has a low absorption of the EUV radiation. In certain embodiments, hydrogen gas can be energized by EUV radiation to generate hydrogen (H*) radicals. The hydrogen radicals can be used for cleaning purposes. Hydrogen radicals reaching the coating surface of the mirror collector 110 can react chemically with metal contamination from a droplet and form a hydride, e.g., metal hydride. When tin (Sn) is used as the droplet, hydrogen radicals can react with tin to form stannane (SnH₄), which is a gaseous byproduct of the EUV generation process. The gaseous SnH₄ can then then pumped out through the outlet 140.

In some embodiments, an EUV lithography apparatus can further include other modules or is integrated with (or coupled with) other modules in some embodiments.

Laser light emitted from an excitation laser system of an EUV apparatus can exhibit a decay in power over time due to the degradation of a gain medium including carbon dioxide. During plasma excitation of carbon dioxide molecules in lasers of an EUV system, up to 60% of the carbon dioxide can decompose into carbon monoxide. The power of the laser beam emitted from the gain medium can decrease along with the relative increase in the concentration of carbon monoxide and decrease in the concentration of carbon dioxide. Catalysts, such as gold, can be placed in contact with the gain medium to catalytically re-combine carbon monoxide and oxygen radicals into carbon dioxide. While such catalytic reactions can mitigate the decomposition of carbon dioxide, a significant amount of carbon monoxide may still be present in the gain medium. Moreover, the efficacy of the catalyst can degrade over time due to contamination. For example, silicon dioxide from a quartz tube housing the gain medium can foul or otherwise cover a catalyst and decrease the efficacy of the catalyst.

The presence of carbon monoxide in the gain medium can reduce the efficiency of the laser and the efficiency of an EUV photolithograph apparatus using the laser for semiconductor device manufacturing. Directly monitoring the gain medium composition by removal of a quartz tube module of a laser generator or amplifier can introduce inaccurate measurements because the composition of the gain medium can differ between a measurement state and an operating state of laser generation or amplification. Also, direct sampling of the gain medium including carbon monoxide poses risks to personnel due to the toxicity of carbon monoxide. The subject matter provided herein permits real-time monitoring of the gain medium composition in a non-invasive manner through emission spectrum analysis. The subject matter provided herein also provides control of the composition of the gain media to improve the power output of the excitation laser system.

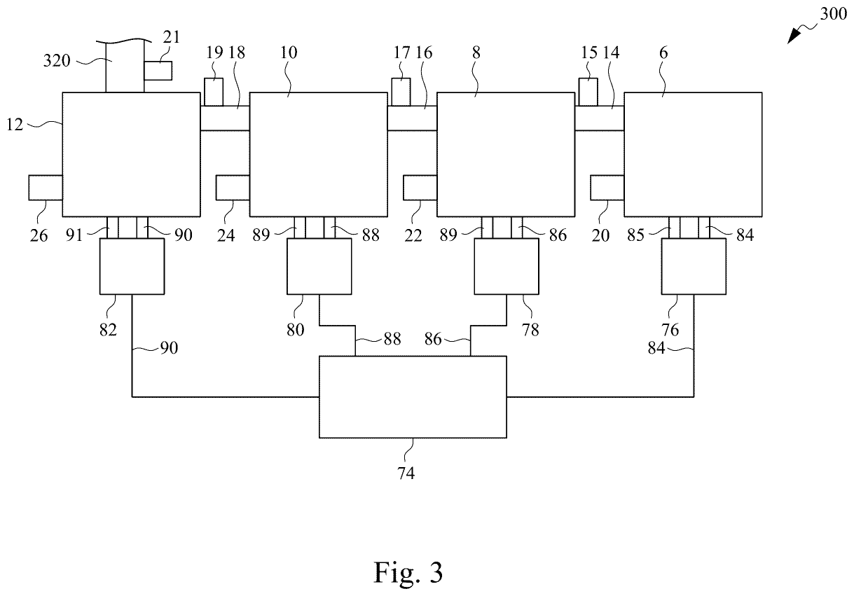

FIG. 3 schematically illustrates an excitation laser system 300 according to embodiments of the disclosure. The excitation laser system 300 includes a laser generator 6, a first laser amplifier 8, a second laser amplifier 10, and a third laser amplifier 12. Additional or fewer laser amplifiers and corresponding components can be provided. The laser generator 6 is connected to the first laser amplifier 8 via a passage 14 through which a laser beam generated by the laser generator can pass. The first laser amplifier 8 is connected to the second laser amplifier 10 via a passage 16 through which the laser beam amplified by the first laser amplifier can pass. The second laser amplifier 10 is connected to the third laser amplifier 12 via a passage 18 through which the laser beam amplified by the second laser amplifier can pass. The third laser amplifier 12 is connected to the guide optics 320 through which the laser beam amplified by the third laser amplifier can pass. Power sensors 15, 17, 19, and 21 are configured to measure laser lower emitted through the passages 14, 16, 18, and the guide optics 320.

The excitation laser system 300 further includes a first optical emission spectrum meter 20 configured to optically capture a first spectrum of light from a first gain medium of the laser generator 6, a second optical emission spectrum meter 22 configured to optically capture a second spectrum of light from a second gain medium of the first laser amplifier 8, a third optical emission spectrum meter 24 configured to optically capture a third spectrum of light from a third gain medium of the second laser amplifier 10, and a fourth optical emission spectrum meter 26 configured to optically capture a fourth spectrum of light from a fourth gain medium of the third laser amplifier 12. In some embodiments, the first, second, third, and fourth optical emission spectrum meters are wirelessly connected to a computing system. In some embodiments, the first, second, third, and fourth optical emission spectrum meters have a wired connection to a computing system. In some embodiments, an optical emission spectrum meter is connectable and movable between the laser generator and the first, second, and third amplifiers.

In some embodiments, a gas supply unit 74 controls a supply, pressure, and flow of gas to gain media in the laser generator 6 and the laser amplifiers 8, 10, 12 through gas manifolds 76, 78, 80, and 82. The gas manifolds are connected to the gas supply unit 74 through gas and control lines 84, 86, 88, and 90. The gas and control lines include gas supply lines for any number of gases included in the gain media and control lines for operating any one or more unit devices (e.g. valves, pumps, vents, and blowers) to control flow and pressure of gases to gain media. Each gas manifold is connected to a gas inlet 84, 86, 88, 90 for feeding gas to gain media and a gas outlet 85, 87, 89, 91 for receiving gas from gain media in the laser generator 6 and the laser amplifiers 8, 10, 12. The gas supply unit 74 and gas manifolds 76, 78, 80, and 82 can be controlled by a computing system.

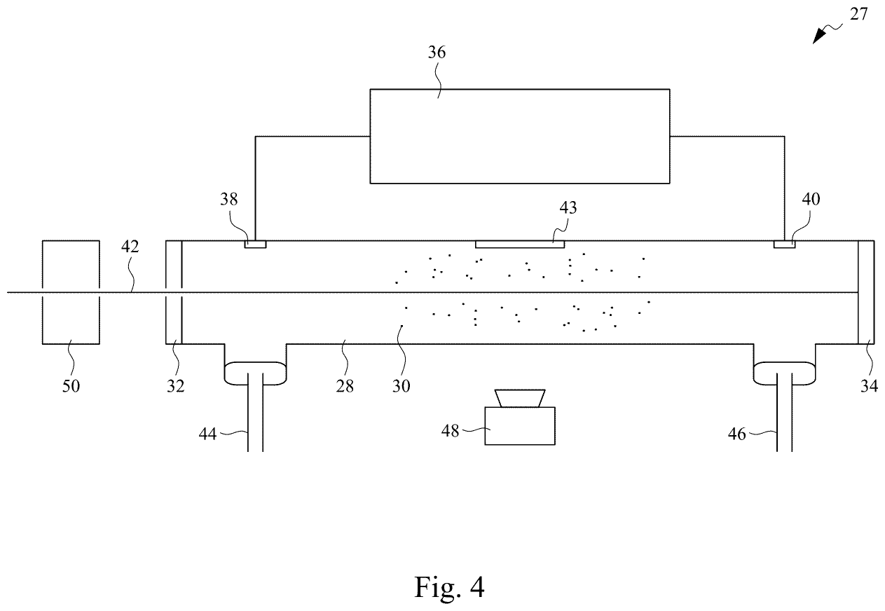

FIG. 4 schematically illustrates an embodiment of a laser generator 27 including a quartz tube 28 containing a gain medium 30. In some embodiments, the laser generator is a carbon dioxide laser and the gain medium 30 includes carbon dioxide, nitrogen, helium, and any byproduct gases such as carbon monoxide. A catalyst 43, e.g. gold catalyst, is disposed in the quartz tube to convert carbon monoxide back to carbon dioxide. The laser generator includes a reflector 34 and an output coupler 32 having a partially reflective surface. A power supply 36 is configured to apply a high voltage between electrodes 38, 40 to stimulate the gain medium 30. As power is applied to the gain medium, molecules of the gain medium enter an excited state and emit photons. The photons are reflected between the reflector 34 and output coupler 32 and ultimately exit the quartz tube as a laser beam 42. The composition, flow, and pressure of the gain medium in the quartz tube is controlled via an inlet 46 and an outlet 44. An optical emission spectrum meter 48 is configured to capture an operating spectrum of light emitted from the excited gain medium 30 in the quartz tube 28. A power sensor 50, such as a pyroelectric sensor, measures an operating power of the laser beam 42. The laser generator 27, optical emission spectrum meter 48, and the power sensor 50 can be controlled by a computing system.

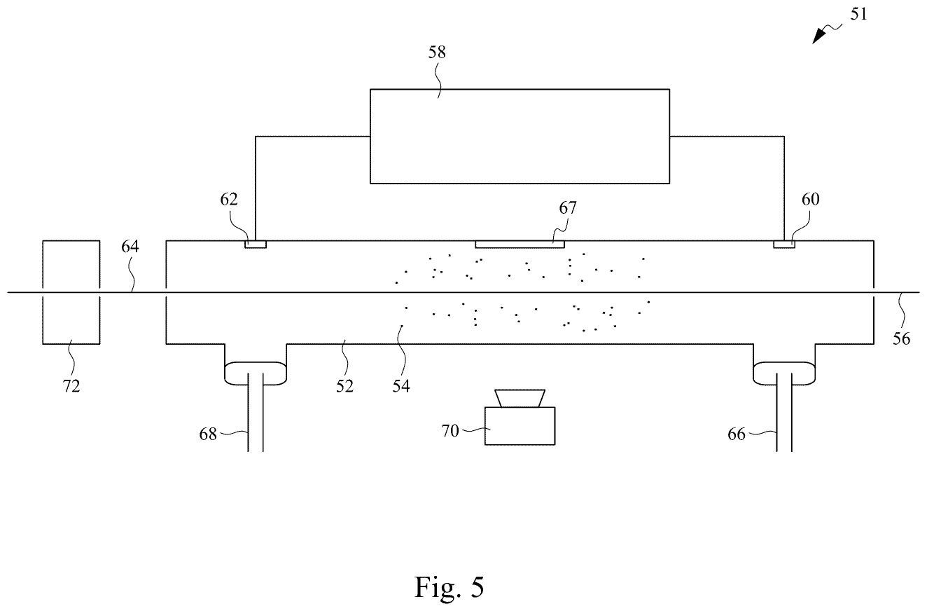

FIG. 5 schematically illustrates an embodiment of a laser amplifier 51 including a quartz tube 52 containing a gain medium 54. In some embodiments, the laser amplifier is used in conjunction with a carbon dioxide laser, and the gain medium 54 includes carbon dioxide, nitrogen, helium, and any byproduct gases such as carbon monoxide. A catalyst 67, e.g. gold catalyst, is disposed in the quartz tube to convert carbon monoxide back to carbon dioxide. In some embodiments, the laser amplifier receives a laser beam 56 from a laser generator or another laser amplifier. In some embodiments, a laser amplifier includes a plurality of mirrors or other reflective surfaces (not shown) to internally reflect the laser beam through the gain medium 54 before the laser beam exits the laser amplifier. A power supply 58 is configured to apply a high voltage between electrodes 60, 62 to stimulate the gain medium 54. As power is applied to the gain medium, molecules of the gain medium enter an excited state and emit photons, which add power to the laser beam 56 to produce an amplified laser beam 64 that exits the laser amplifier 51. The composition, flow, and pressure of the gain medium in the quartz tube is controlled via an inlet 66 and an outlet 68. An optical emission spectrum meter 70 is configured to capture an operating spectrum of light emitted from the excited gain medium 54 in the quartz tube 52. A power sensor 72, such as a pyroelectric sensor, measures an operating power of the laser beam 64 exiting the laser amplifier 51. The laser amplifier 51, optical emission spectrum meter 70, and the power sensor 72 can be controlled by a computing system. In some embodiments, a plurality of laser amplifiers are arranged in series to progressively amplify a laser beam emitted from a laser generator.

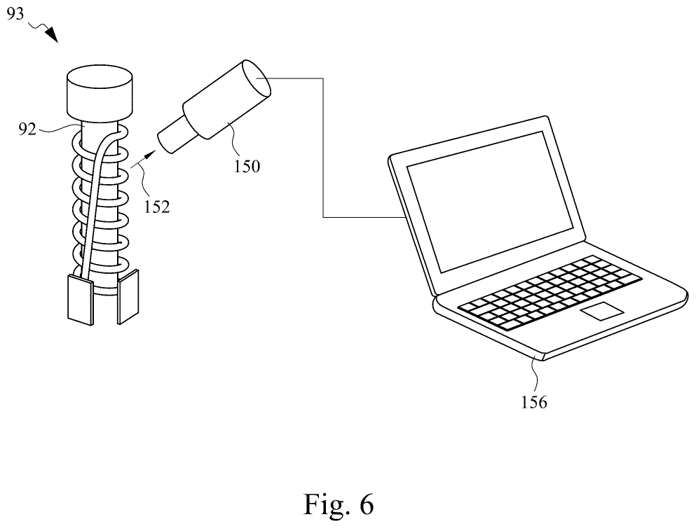

FIG. 6 schematically illustrates an optical emission spectrum meter 150 capturing a spectrum of light 152 emitted from an excited gain medium inside a quartz tube 92 of a laser generator or laser amplifier 93, according to an embodiment. In some embodiments, the optical emission spectrum meter 150 captures a spectrum of light emitted from excited gain medium inside a quartz tube 92. The optical emission spectrum meter 150 is connected to a computing system 156, according to an embodiment. In some embodiments, an optical emission spectrum meter is photo detector. An example of an optical emission spectrum meter is a CCS200 Compact Spectrometer from Thorlabs, Inc.

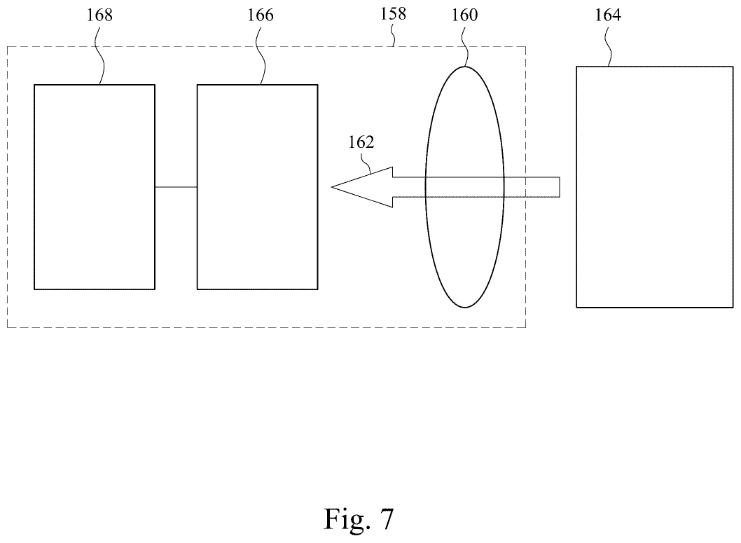

FIG. 7 schematically illustrates components of an optical emission spectrum meter 158, according to an embodiment. Emission collection optics 160 transmit a spectrum of light 162 emitted from an excited gain medium 164. The spectrum of light 162 passes through the emission collection optics 160 and is detected by a spectrum meter component 166. A signal processor 168 processes a spectral signal generated by the spectrum meter component 166. In some embodiments, one or more of the emission collection optics and the signal processor are provided external to the optical emission spectrum meter and not included in the optical emission spectrum meter. In some embodiments, a signal processor is integrated in a computing system configured to receive and process a spectral signal. In some embodiments, the emission collection optics are integrated in a laser generator or a laser amplifier. In some embodiments, emission optics include fiber optic cable configured to convey light emitted from the gain media to the spectrum meter component. In some embodiments, the emission optics include one or more lenses configured to transmit or otherwise alter light emitted from the gain media to the spectrum meter component. In some embodiments, the emission optics include both a fiber optic cable and a lens.

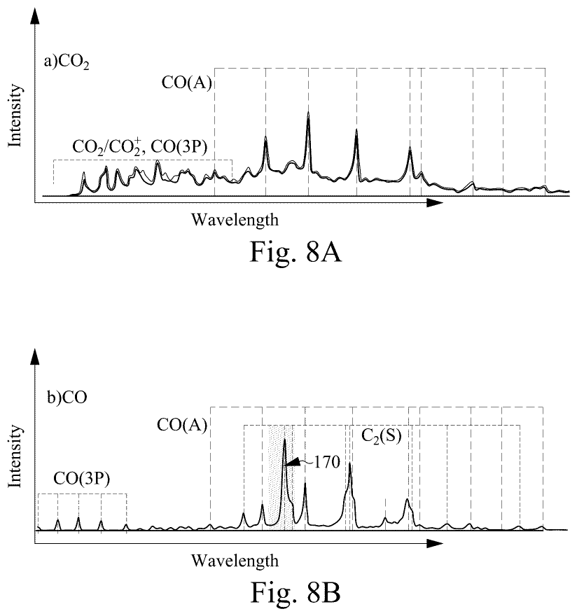

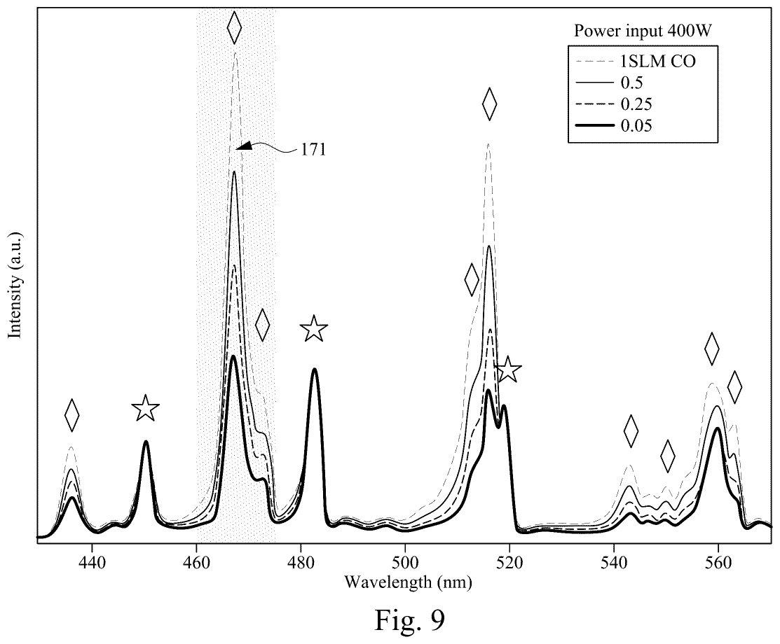

FIG. 8A illustrates a plot of an optical emission spectrum showing an abundance of carbon dioxide, while FIG. 8B illustrates a plot of an optical emission spectrum including a peak 170 at about 470 nm corresponding to an abundance of carbon monoxide. FIG. 9 illustrates a plot of an optical emission spectrum including a peak 171 corresponding to the presence of carbon monoxide. Since the characteristic emission spectrum is different between carbon dioxide and carbon monoxide, an optical emission spectrum can be used to monitor the carbon monoxide content of a gain medium.

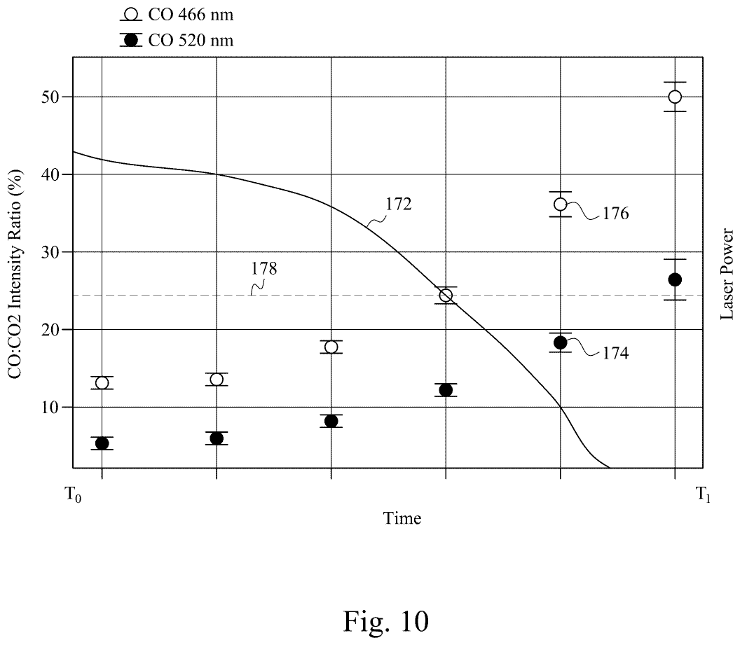

FIG. 10 illustrates a plot 172 representing the operating power of a laser beam from a laser generator over a period of time, according to an embodiment. The plot 172 of the operating power is overlaid with plots 174, 176 showing ratios (expressed as a percentage) of carbon monoxide to carbon dioxide in a gain media of the laser generator over the same period of time. The ratios are determined from peaks representing carbon monoxide at two different wavelengths in an optical emission spectrum obtained from the gain medium. The series in plot 174 represents the percentage of carbon monoxide in the gain medium determined from a peak at 520 nm in the spectrum, and the series in plot 176 represents the percentage of carbon monoxide determined from a peak at 466 nm in the spectrum. The horizontal axis represents time, starting at T₀, when the laser generator operates at a high-power state or a target power, up to time T₁ elapsed after T₀. Line 178 represents a threshold power value of the laser generator. While FIG. 10 represents the operating conditions of a laser generator over time, analogous plots to those illustrated in FIG. 10 can be obtained from a laser amplifier.

In some embodiments, the operation of a laser generator or a laser amplifier is controlled such that the power of a laser beam emitted therefrom is maintained above the threshold power value 178. In some embodiments, the operation of a laser generator or a laser amplifier is adjusted when the laser power falls below the threshold power value 178. In some embodiments, the operation of the laser generator or the laser amplifier is adjusted such that the power of the laser beam emitted therefrom is returned to the power condition at time T₀, or to a power condition at any time between time T₀ and the time of measurement of the operating power or a reference amount of carbon monoxide in the gain medium. In some embodiments, the amount of carbon monoxide in either one of the plots 174 and 176, or an average thereof, at the time of the desired target power of the laser beam represents a reference spectrum. The reference spectrum can represent a reference amount of carbon monoxide in a gain medium corresponding to a laser beam previously operating at a higher target power. The reference amount of carbon monoxide can be compared with an amount of carbon monoxide determined from a spectrum of light emitted from the gain medium at the time of taking measurement, such as when the laser power falls below the threshold power value. In some embodiments, a flow rate of carbon dioxide to the gain medium and a pressure of carbon dioxide in the gain medium is adjusted to reduce the amount of carbon monoxide in the gain medium toward the reference amount of carbon monoxide, to increase the power of the laser beam emitted from the gain medium.

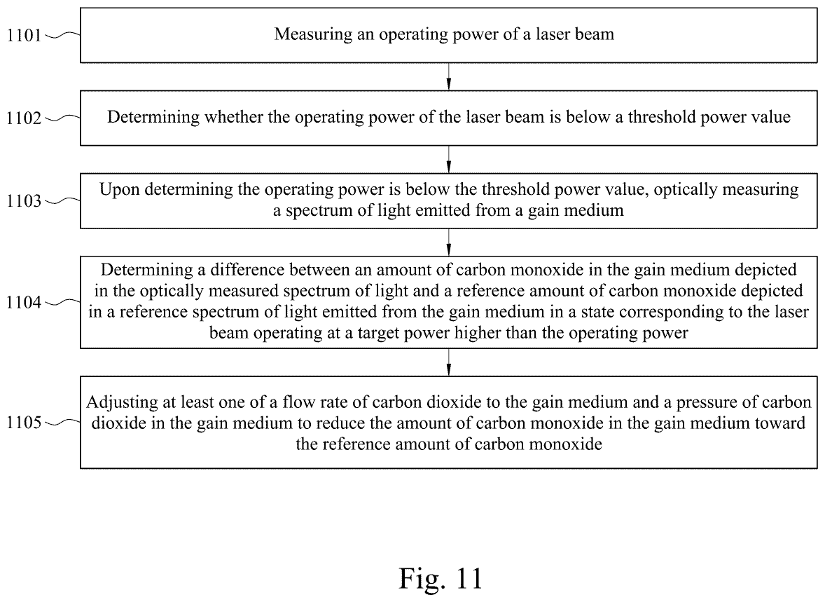

FIG. 11 illustrates a method operating an excitation laser system of an EUV photolithography apparatus, according to some embodiments. The method includes an operation 1101 of measuring an operating power of a laser beam in the excitation laser system. In some embodiments, the operating power is measured using a power sensor. In some embodiments, the laser beam is maintained in a gain medium including carbon dioxide. In some embodiments the gain medium resides in a laser generator. In some embodiments, the gain medium resides in the laser generator 6 in shown in FIG. 3. In some embodiments, the gain medium is maintained in the laser generator 27 shown in FIG. 4. In some embodiments, the gain medium resides in a laser amplifier. In some embodiments, the gain medium resides in any one or more of the laser amplifiers 8, 10, 12 in shown in FIG. 3. In some embodiments, the gain medium resides in the laser amplifier 51 in shown in FIG. 5. In some embodiments, the laser beam is maintained by the gain media of one or more of a laser generator and a laser amplifier.

The method further includes an operation 1102 of determining whether the operating power of the laser beam is below a threshold power value. In some embodiments, a computing system is configured to compare the operating power measured by the power sensor with the threshold power value. In an embodiment, one or more of the power sensors 15, 17, 19, and 21 in FIG. 3 are used to determine the operating power of a laser beam exiting the laser generator 6, or the laser amplifiers 8, 10, 12. In an embodiment, the power sensor 50 shown in FIG. 4 is used to determine the operating power of the laser beam exiting the laser generator 27. In an embodiment, the power sensor 72 shown in FIG. 5 is used to determine the operating power of the laser beam exiting the laser amplifier 51.

The method further includes an operation 1103 of optically measuring a spectrum of light emitted from the gain medium upon determining the operating power of the laser beam is below the threshold value. In some embodiments, optically measuring the spectrum of the laser beam is conducted using optical emission spectroscopy. In some embodiments, the spectrum of light is optically measured using an optical emission spectrum meter. In some embodiments, the optical emission spectrum meter is connected to a computing system. In some embodiments, any one or more of the first, second, third, and fourth optical emission spectrum meters 20, 22, 24, 26 shown in FIG. 3 are used to optically measure the spectrum of light emitted from gain media. In some embodiments, the optical emission spectrum meter 48 shown in FIG. 4 is used to optically measure a spectrum of light. In some embodiments, the optical emission spectrum meter 70 shown in FIG. 5 is used to optically measure a spectrum of light.

The method further includes an operation 1104 of determining a difference between an amount of carbon monoxide in the gain medium depicted in the optically measured spectrum of light and a reference amount of carbon monoxide depicted in a reference spectrum of light emitted from the gain medium in a state corresponding to the laser beam operating at a target power higher than the operating power. In an embodiment, the amount of carbon monoxide in the gain medium depicted in the optically measured spectrum is measured at any time after time T₀ in FIG. 10, and the reference amount of carbon monoxide depicted in a reference spectrum of the gain medium corresponds to the carbon monoxide concentration at time T₀, or any time between T₀ and the time of measurement. In some embodiments, the operating power and carbon monoxide concentration depicted at time T₀ is considered a golden condition for the gain medium of the laser generator or laser amplifier.

The method further includes an operation 1105 of adjusting at least one of a flow rate of carbon dioxide to the gain medium and a pressure of carbon dioxide in the gain medium to reduce the amount of carbon monoxide in the gain medium toward the reference amount of carbon monoxide. In some embodiments, the method includes increasing the flow rate of carbon dioxide to the gain medium. In some embodiments, the method includes decreasing the pressure of carbon dioxide in the gain medium. In some embodiments, the method includes increasing the flow rate of carbon dioxide to the gain medium and decreasing the pressure of carbon dioxide in the gain medium. In some embodiments, the method includes adjusting at least one of a flow rate of carbon dioxide to the gain medium and a pressure of carbon dioxide in the gain medium to increase the operating power of the laser beam toward a target power such as a power at a golden condition.

Increasing the flow rate of carbon dioxide to the gain medium increases the amount of carbon dioxide relative to carbon monoxide in the gain medium, permitting greater photon generation through the excitation of carbon dioxide molecules, according to some embodiments. The greater photon generation can increase the power of the laser beam. Decreasing the pressure of carbon dioxide in the gain medium increases the mean free path between molecules in the gain medium and slows the decomposition of carbon dioxide to carbon monoxide via the collision of carbon dioxide molecules, according to some embodiments. Slowing the decomposition of carbon dioxide to carbon monoxide can allow the catalytic conversion of carbon monoxide to carbon dioxide using a catalyst, to increase the concentration of carbon dioxide in the gain medium.

In some embodiments, adjusting at least one of a flow rate of carbon dioxide to the gain medium and a pressure of carbon dioxide in the gain medium to reduce the amount of carbon monoxide in the gain medium toward the reference amount of carbon monoxide is conducted using the gas supply unit 74, gas and control lines 84, 86, 88, and 90, and gas manifolds 76, 78, 80, and 82 shown in FIG. 3. In some embodiments, adjusting at least one of a flow rate of carbon dioxide to the gain medium and a pressure of carbon dioxide in the gain medium to reduce the amount of carbon monoxide in the gain medium toward the reference amount of carbon monoxide is conducted using the inlet 46 and outlet 44 shown in FIG. 4. In some embodiments, adjusting at least one of a flow rate of carbon dioxide to the gain medium and a pressure of carbon dioxide in the gain medium to reduce the amount of carbon monoxide in the gain medium toward the reference amount of carbon monoxide is conducted using the inlet 66 and outlet 68 shown in FIG. 5.

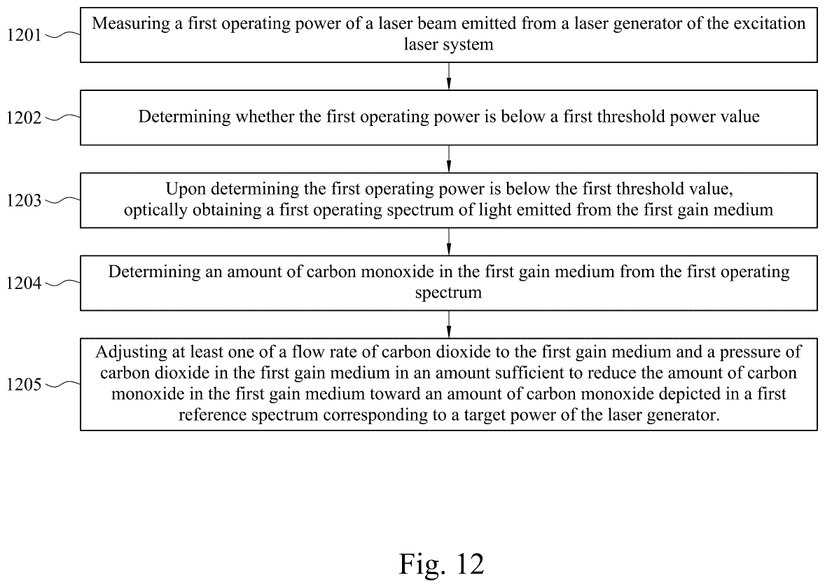

FIG. 12 illustrates a method operating an excitation laser system, according to some embodiments. The method includes an operation 1201 of measuring a first operating power of a laser beam emitted from a laser generator of the excitation laser system. The laser generator contains a first gain medium including carbon dioxide, and the first gain medium maintains the laser beam. The method further includes an operation 1202 of determining whether the first operating power is below a first threshold value. The method further includes an operation 1203 of, upon determining the first operating power is below the first threshold value, optically obtaining a first operating spectrum of light emitted from the first gain medium. The method further includes an operation 1204 of determining an amount of carbon monoxide in the first gain medium from the first operating spectrum. The method further includes an operation 1205 of adjusting at least one of a flow rate of carbon dioxide to the first gain medium and a pressure of carbon dioxide in the first gain medium sufficient to reduce the amount of carbon monoxide in the first gain medium toward an amount of carbon monoxide depicted in a first reference spectrum corresponding to a target power of the laser generator. The operations in FIG. 12 can be independently applied to the laser generator, the laser amplifier, or a combination of the laser generator with one or more laser amplifiers, according to various embodiments.

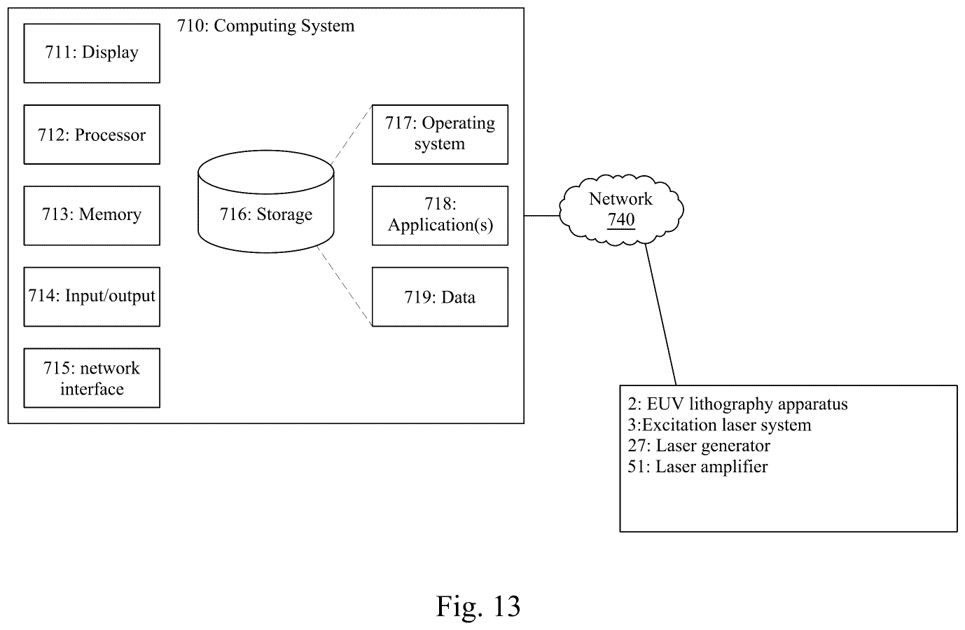

FIG. 13 is a block diagram illustrating an example of a computing system 710 for controlling the operation of one or more of the EUV lithography apparatus 2, the excitation laser system 300, the laser generator 27, and the laser amplifier 51, and optionally any one or more optical emission spectrum meters, gas supply units, gas manifold, among other components explicitly or implicitly described herein, according to various embodiments. In some embodiments, the computing system 710 is implemented using hardware or a combination of software and hardware, either in a dedicated server, integrated into another entity, or distributed across multiple entities such as via a cloud or wired network. According to various embodiments, computing system 710 is communicably connected to one or more of the EUV lithography apparatus 2, the excitation laser system 300, the laser generator 27, and the laser amplifier 51, and any other component explicitly or implicitly described herein using a wireless or wired network 740 to permit data exchange therebetween.

The computing system 710 includes a display 711, a processor 712, a memory 713, an input/output interface 714, a network interface 715, and a storage 716 storing an operating system 717, programs or applications 718 such as applications for controlling the EUV lithography apparatus 2, the excitation laser system 300, the laser generator 27, and the laser amplifier 51, and any other component explicitly or implicitly described herein. The processor 712 can be a general-purpose microprocessor, a microcontroller, or the like. The storage 716 can be a random access memory (RAM), a flash memory, a read-only memory (ROM), a hard or optical disk, or any other suitable storage device, for storing information and instructions to be executed by processor 712. The processor 712 and storage 716 can be supplemented by, or incorporated in, special purpose logic circuitry.

The network interface 715 can include networking interface cards, such as Ethernet cards and modems. In some embodiments, the input/output interface 714 is configured to connect to a plurality of devices, such as an input device and/or an output device. Example input devices include a keyboard and a pointing device, e.g., a mouse or a trackball, by which a user can provide input to the computing system 710. Example output devices include display devices, such as LED (light emitting diode) or LCD (liquid crystal display) screens for displaying information to the user.

The applications 718 can include instructions which, when executed by the computing system 710 (or a processor 712 thereof), causes the computing system 710 (or the processor 712 thereof) to control the EUV lithography apparatus 2, the excitation laser system 300, the laser generator 27, and the laser amplifier 51, and any other component explicitly or implicitly described herein, and perform other operations, methods, and/or processes that are explicitly or implicitly described in the present disclosure.

The data 719 can include data including parameters used in the control operations, data that is received, for example, through the input/output interface 714 or through the network interface 715 transmitted from the EUV lithography apparatus 2, the excitation laser system 300, the laser generator 27, and the laser amplifier 51, and any other component explicitly or implicitly described herein, data for displaying on the display 711, data that is transmitted to or from the EUV lithography apparatus 2, the excitation laser system 300, the laser generator 27, and the laser amplifier 51, and any other component explicitly or implicitly described herein via the network 740, or data generated during operation of the computing system 710.

In some embodiments, the computing device is configured to control one or more power sensors to measure operating power of one or more of a laser generator and one or more laser amplifiers. In some embodiments, the computing device is programmed to determine whether a measured operating power is below a threshold power value. In some embodiments, the computing device is configured to control one or more optical emission spectrum meters to optically capture a spectrum of light from one or more of the laser generator and one or more of the laser amplifiers upon determining a corresponding operating power is below the threshold power value. In some embodiments, the computing device is configured to determine an amount of carbon monoxide in the gain media of one or more of the laser generator and one or more the laser amplifiers from a corresponding measured spectrum of light. In some embodiments, the computing device is configured to control a gas supply unit to adjust at least one of a flow rate of carbon dioxide to the gain media, and a pressure of carbon dioxide in the gain media, to reduce the amount of carbon monoxide in the gain media toward an amount of carbon monoxide depicted in a corresponding reference spectrum corresponding to target powers of one or more of the laser generator and one or more of the laser amplifiers.

Subject matter of the present disclosure serves to improve the performance, maintenance, and operation of EUV lithography systems. Subject matter of the present disclosure can be utilized to measure a composition of a laser gain medium in a non-invasive manner and control or otherwise adjust the composition of the gain medium to maintain the power of the laser or return the laser to a target power state. Subject matter of the present disclosure serves to avoid the need to obtain physical samples of gain media that may otherwise include hazardous materials such as carbon monoxide. Subject matter of the present disclosure also serves to avoid compositional inaccuracy caused by removing physical gas samples from a gain medium. Subject matter of the present disclosure also avoids the need to shut down a laser apparatus to obtain a sample of a gain medium.

According to an embodiment, a method of operating an excitation laser system of an extreme ultraviolet (EUV) photolithography apparatus includes measuring an operating power of a laser beam in the excitation laser system, wherein the laser beam is maintained in a gain medium including carbon dioxide. The method further includes determining whether the operating power of the laser beam is below a threshold power value. The method further includes, upon determining the operating power of the laser beam is below the threshold power value, optically measuring a spectrum of light emitted from the gain medium. The method further includes determining a difference between an amount of carbon monoxide in the gain medium depicted in the optically measured spectrum of light and a reference amount of carbon monoxide depicted in a reference spectrum of light emitted from the gain medium in a state corresponding to the laser beam operating at a target power higher than the operating power. The method further includes adjusting at least one of a flow rate of carbon dioxide to the gain medium and a pressure of carbon dioxide in the gain medium to reduce the amount of carbon monoxide in the gain medium. In an embodiment, the gain medium resides in a laser generator. In an embodiment, the gain medium resides in a laser amplifier. In an embodiment, the optically measuring the spectrum of light is conducted using optical emission spectroscopy. In an embodiment, the method includes increasing the flow rate of carbon dioxide to the gain medium. In an embodiment, the method includes decreasing the pressure of carbon dioxide in the gain medium. In an embodiment, the method includes increasing the flow rate of carbon dioxide to the gain medium and decreasing the pressure of carbon dioxide in the gain medium.

According to another embodiment, a method of operating an excitation laser system includes measuring a first operating power of a laser beam emitted from a laser generator of the excitation laser system, wherein the laser generator contains a first gain medium including carbon dioxide, and the first gain medium maintains the laser beam. The method further includes determining whether the first operating power is below a first threshold power value. The method further includes upon determining the first operating power is below the first threshold power value, optically measuring a first operating spectrum of light emitted from the first gain medium, and determining an amount of carbon monoxide in the first gain medium depicted in the first operating spectrum. The method further includes adjusting at least one of a flow rate of carbon dioxide to the first gain medium and a pressure of carbon dioxide in the first gain medium in an amount sufficient to reduce the amount of carbon monoxide in the first gain medium. In an embodiment, the method includes increasing the flow rate of carbon dioxide to the first gain medium. In an embodiment, the method includes reducing the pressure of carbon dioxide in the first gain medium. In an embodiment, the method further includes measuring a second operating power of the laser beam emitted from a laser amplifier of the excitation laser system, wherein the laser amplifier receives the laser beam from the laser generator, the laser amplifier contains a second gain medium including carbon dioxide, and the second gain medium maintains the laser beam; determining whether the second operating power is below a second threshold power value; upon determining the second operating power is below the second threshold power value, optically obtaining a second operating spectrum of light emitted from the second gain medium, and determining an amount of carbon monoxide in the second gain medium from the second operating spectrum; and adjusting at least one of a flow rate of carbon dioxide to the second gain medium and a pressure of carbon dioxide in the second gain medium in an amount sufficient to reduce the amount of carbon monoxide in the second gain medium. In an embodiment, the method includes increasing the flow rate of carbon dioxide to the second gain medium. In an embodiment, the method includes reducing the pressure of carbon dioxide in the second gain medium.

In another embodiment, an excitation laser system includes a laser generator configured to generate a laser beam from a first gain medium including carbon dioxide. The excitation laser system further includes a first power sensor configured to measure a first operating power of the laser beam exiting the laser generator. The excitation laser system further includes a first optical emission spectrum meter configured to optically capture a first spectrum of light from the first gain medium. The excitation laser system further includes a gas supply unit configured to control a supply of carbon dioxide to the first gain medium. The excitation laser system further includes a computing system programmed to conduct operations including: controlling the first power sensor to measure the first operating power, determining whether the first operating power is below a first threshold power value, upon determining the first operating power is below the first threshold power value, controlling the first optical emission spectrum meter to optically capture the first spectrum of light, determining an amount of carbon monoxide in the first gain medium from the first spectrum of light, and controlling the gas supply unit to adjust at least one of a flow rate of carbon dioxide to the first gain medium and a pressure of carbon dioxide in the first gain medium to reduce the amount of carbon monoxide in the first gain medium. In an embodiment, the computing system is programmed to control the gas supply unit to increase the flow rate of carbon dioxide to the first gain medium. In an embodiment, the computing system is programmed to control the gas supply unit to reduce the pressure of carbon dioxide in the first gain medium. In an embodiment, the excitation laser system further includes a first laser amplifier configured to amplify the laser beam using a second gain medium including carbon dioxide, a second power sensor configured to measure a second operating power of the laser beam exiting the first laser amplifier; and a second optical emission spectrum meter configured to optically capture a second spectrum of light from the second gain medium, wherein the computing system is further programmed to conduct operations including: controlling the second power sensor to measure the second operating power, determining whether the second operating power is below a second threshold power value, upon determining the second operating power is below the second threshold power value, controlling the second optical emission spectrum meter to optically capture the second spectrum of light, determining an amount of carbon monoxide in the second gain medium from the second spectrum of light, and controlling the gas supply unit to adjust at least one of a flow rate of carbon dioxide to the second gain medium and a pressure of carbon dioxide in the second gain medium to reduce the amount of carbon monoxide in the second gain medium. In an embodiment, the excitation laser system further includes a second laser amplifier configured to amplify the laser beam using a third gain medium including carbon dioxide; a third power sensor configured to measure a third operating power of the laser beam exiting the second laser amplifier; and a third optical emission spectrum meter configured to optically capture a third spectrum of light from the third gain medium, wherein the computing system is further programmed to conduct operations including: controlling the third power sensor to measure the third operating power, determining whether the third operating power is below a third threshold power value, upon determining the third operating power is below the third threshold power value, controlling the third optical emission spectrum meter to optically capture the third spectrum of light, determining an amount of carbon monoxide in the third gain medium from the third spectrum of light, and controlling the gas supply unit to adjust at least one of a flow rate of carbon dioxide to the third gain medium and a pressure of carbon dioxide in the third gain medium to reduce the amount of carbon monoxide in the third gain medium. In an embodiment, the excitation laser system further includes a third laser amplifier configured to amplify the laser beam using a fourth gain medium including carbon dioxide; a fourth power sensor configured to measure a fourth operating power of the laser beam exiting the third laser amplifier; and a fourth optical emission spectrum meter configured to optically capture a fourth spectrum of light from the fourth gain medium, wherein the computing system is further programmed to conduct operations including: controlling the fourth power sensor to measure the fourth operating power, determining whether the fourth operating power is below a fourth threshold power value, upon determining the third operating power is below the third threshold power value, controlling the fourth optical emission spectrum meter to optically capture the fourth spectrum of light, determining an amount of carbon monoxide in the fourth gain medium from the fourth spectrum of light, and controlling the gas supply unit to adjust at least one of a flow rate of carbon dioxide to the fourth gain medium and a pressure of carbon dioxide in the fourth gain medium to reduce the amount of carbon monoxide in the fourth gain medium. In an embodiment, at least one of the laser generator, the first laser amplifier, the second laser amplifier, or the third laser amplifier, includes a quartz tube configured to contain the first gain medium in an excited state. In an embodiment, at least one of the first, second, third, or fourth optical emission spectrum meters is configured to respectively capture the first, second, or fourth spectrum of light emitted from the quartz tube. In an embodiment, an extreme ultraviolet (EUV) photolithography apparatus includes excitation laser system.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating an excitation laser system of an extreme ultraviolet (EUV) photolithography apparatus, the method comprising:
measuring an operating power of a laser beam in the excitation laser system, wherein the laser beam is maintained in a gain medium including carbon dioxide;
determining whether the operating power of the laser beam is below a threshold power value;
upon determining the operating power of the laser beam is below the threshold power value, optically measuring a spectrum of light emitted from the gain medium;
determining a difference between an amount of carbon monoxide in the gain medium depicted in the optically measured spectrum of light and a reference amount of carbon monoxide depicted in a reference spectrum of light emitted from the gain medium in a state corresponding to the laser beam operating at a target power higher than the operating power; and
adjusting at least one of a flow rate of carbon dioxide to the gain medium and a pressure of carbon dioxide in the gain medium to reduce the amount of carbon monoxide in the gain medium.

2. The method of claim 1, wherein the gain medium resides in a laser generator.

3. The method of claim 1, wherein the gain medium resides in a laser amplifier.

4. The method of claim 1, wherein the optically measuring the spectrum of light is conducted using optical emission spectroscopy.

5. The method of claim 1, wherein the method comprises increasing the flow rate of carbon dioxide to the gain medium.

6. The method of claim 1, wherein the method comprises decreasing the pressure of carbon dioxide in the gain medium.

7. The method of claim 1, wherein the method comprises increasing the flow rate of carbon dioxide to the gain medium and decreasing the pressure of carbon dioxide in the gain medium.

8. A method of operating an excitation laser system comprising:
measuring a first operating power of a laser beam emitted from a laser generator of the excitation laser system, wherein the laser generator contains a first gain medium including carbon dioxide, and the first gain medium maintains the laser beam;
determining whether the first operating power is below a first threshold power value;
upon determining the first operating power is below the first threshold power value, optically measuring a first operating spectrum of light emitted from the first gain medium, and determining an amount of carbon monoxide in the first gain medium depicted in the first operating spectrum; and
adjusting at least one of a flow rate of carbon dioxide to the first gain medium and a pressure of carbon dioxide in the first gain medium in an amount sufficient to reduce the amount of carbon monoxide in the first gain medium.

9. The method of claim 8, wherein the method comprises increasing the flow rate of carbon dioxide to the first gain medium.

10. The method of claim 8, wherein the method comprises reducing the pressure of carbon dioxide in the first gain medium.

11. The method of claim 8, further comprising:
measuring a second operating power of the laser beam emitted from a laser amplifier of the excitation laser system, wherein the laser amplifier receives the laser beam from the laser generator, the laser amplifier contains a second gain medium including carbon dioxide, and the second gain medium maintains the laser beam;
determining whether the second operating power is below a second threshold power value;
upon determining the second operating power is below the second threshold power value, optically obtaining a second operating spectrum of light emitted from the second gain medium, and determining an amount of carbon monoxide in the second gain medium from the second operating spectrum; and
adjusting at least one of a flow rate of carbon dioxide to the second gain medium and a pressure of carbon dioxide in the second gain medium in an amount sufficient to reduce the amount of carbon monoxide in the second gain medium.

12. The method of claim 11, wherein the method comprises increasing the flow rate of carbon dioxide to the second gain medium.

13. The method of claim 11, wherein the method comprises reducing the pressure of carbon dioxide in the second gain medium.

14. An excitation laser system comprising:
a laser generator configured to generate a laser beam from a first gain medium comprising carbon dioxide;
a first power sensor configured to measure a first operating power of the laser beam exiting the laser generator;
a first optical emission spectrum meter configured to optically capture a first spectrum of light from the first gain medium;
a gas supply unit configured to control a supply of carbon dioxide to the first gain medium;
a computing system programmed to conduct operations comprising:
controlling the first power sensor to measure the first operating power,
determining whether the first operating power is below a first threshold power value,
upon determining the first operating power is below the first threshold power value, controlling the first optical emission spectrum meter to optically capture the first spectrum of light,
determining an amount of carbon monoxide in the first gain medium from the first spectrum of light, and
controlling the gas supply unit to adjust at least one of a flow rate of carbon dioxide to the first gain medium and a pressure of carbon dioxide in the first gain medium to reduce the amount of carbon monoxide in the first gain medium.

15. The excitation laser system of claim 14, further comprising:
a first laser amplifier configured to amplify the laser beam using a second gain medium comprising carbon dioxide;
a second power sensor configured to measure a second operating power of the laser beam exiting the first laser amplifier; and
a second optical emission spectrum meter configured to optically capture a second spectrum of light from the second gain medium,
wherein the computing system is further programmed to conduct operations comprising:
controlling the second power sensor to measure the second operating power,
determining whether the second operating power is below a second threshold power value,
upon determining the second operating power is below the second threshold power value, controlling the second optical emission spectrum meter to optically capture the second spectrum of light,
determining an amount of carbon monoxide in the second gain medium from the second spectrum of light, and
controlling the gas supply unit to adjust at least one of a flow rate of carbon dioxide to the second gain medium and a pressure of carbon dioxide in the second gain medium to reduce the amount of carbon monoxide in the second gain medium.

16. The excitation laser system of claim 14, wherein the computing system is programmed to control the gas supply unit to increase the flow rate of carbon dioxide to the first gain medium.

17. The excitation laser system of claim 14, wherein the computing system is programmed to control the gas supply unit to reduce the pressure of carbon dioxide in the first gain medium.

18. The excitation laser system of claim 15, further comprising:
a second laser amplifier configured to amplify the laser beam using a third gain medium comprising carbon dioxide;
a third power sensor configured to measure a third operating power of the laser beam exiting the second laser amplifier; and
a third optical emission spectrum meter configured to optically capture a third spectrum of light from the third gain medium,
wherein the computing system is further programmed to conduct operations comprising:
controlling the third power sensor to measure the third operating power,
determining whether the third operating power is below a third threshold power value,
upon determining the third operating power is below the third threshold power value, controlling the third optical emission spectrum meter to optically capture the third spectrum of light,
determining an amount of carbon monoxide in the third gain medium from the third spectrum of light, and
controlling the gas supply unit to adjust at least one of a flow rate of carbon dioxide to the third gain medium and a pressure of carbon dioxide in the third gain medium to reduce the amount of carbon monoxide in the third gain medium.

19. The excitation laser system of claim 14, wherein the laser generator comprises a quartz tube configured to contain the first gain medium in an excited state.

20. The excitation laser system of claim 19, wherein the first optical emission spectrum meter is configured to capture the first spectrum of light emitted from the quartz tube.
